(19) United States
(12) Patent Application Publication
(10) Pub. No.: US 2008/0241756 A1
(43) Pub. Date: Oct. 2, 2008

(54) ENHANCING LITHOGRAPHY FOR VIAS AND CONTACTS BY USING DOUBLE EXPOSURE BASED ON LINE-LIKE FEATURES

(76) Inventors: Matthias Lehr, Dresden (DE); Bjoern Eggenstein, Dresden (DE)

Correspondence Address: J. Mike Amerson;Williams, Morgan & Amerson, P.C., Suite 1100, 10333 Richmond, Houston, TX, 77042, US

(21) Appl. No.: 11/936,144

(22) Filed: Nov. 7, 2007

(30) Foreign Application Priority Data
Mar. 30, 2007 (DE) 10 2007 015 499.4

(51) Int. Cl. G03F 7/20

(52) U.S. Cl. 430/312

(57) ABSTRACT

By performing a double exposure process on the basis of bar-like or line-like features, critical via and contact openings may be defined as an intersection, thereby obtaining the desired design dimension on the basis of less critical lithography process windows. Hence, process flexibility may be enhanced while overall throughput may not be substantially negatively affected.

### BACKGROUND OF THE INVENTION

1. Field of the Invention

Generally, the subject matter disclosed herein relates to the manufacture of integrated circuits, and, more particularly, to forming contact features for connecting contact areas or metal regions of semiconductor devices with conductive lines or regions, such as metal lines, in a higher wiring level of the semiconductor device, wherein the contact features are formed on the basis of advanced photolithography techniques.

2. Description of the Related Art

The fabrication of microstructures, such as integrated circuits, requires tiny regions of precisely controlled size to be formed in one or more material layers of an appropriate substrate, such as a silicon substrate, a silicon-on-insulator (SOI) substrate or other suitable carrier materials. These tiny regions of precisely controlled size are typically defined by patterning the material layer(s) by applying lithography, etch, implantation and deposition processes and the like, wherein typically, at least in a certain stage of the patterning process, a mask layer may be formed over the material layer(s) to be treated to define these tiny regions. Generally, a mask layer may consist of or may be formed by means of a layer of photoresist that is patterned by a lithographic process, typically a photolithography process. During the photolithography process, the resist may be spin-coated onto the substrate surface and then selectively exposed to ultraviolet radiation through a corresponding lithography mask, such as a reticle, thereby imaging the reticle pattern into the resist layer to form a latent image therein. After developing the photoresist, depending on the type of resist, positive resist or negative resist, the exposed portions or the non-exposed portions are removed to form the required pattern in the layer of photoresist. Based on this resist pattern, actual device patterns may be formed by further manufacturing processes, such as etch, implantation and anneal processes and the like.

Since the dimensions of the patterns in sophisticated integrated microstructure devices are steadily decreasing, the equipment used for patterning device features has to meet very stringent requirements with regard to resolution and overlay accuracy of the involved fabrication processes. In this respect, resolution is considered as a measure for specifying the consistent ability to print minimum size images under conditions of predefined manufacturing variations. One important factor in improving the resolution is represented by the lithographic process, in which patterns contained in the photo mask or reticle are optically transferred to the substrate via an optical imaging system. Therefore, great efforts are made to steadily improve optical properties of the lithographic system, such as numerical aperture, depth of focus and wavelength of the light source used.

The resolution of the optical patterning process may, therefore, significantly depend on the imaging capability of the equipment used, the photoresist materials for the specified exposure wavelength and the target critical dimensions of the device features to be formed in the device level under consideration. For example, gate electrodes of field effect transistors, which represent an important component of modern logic devices, may be 50 nm and even less for currently produced devices with significantly reduced dimensions for device generations that are currently under development. Similarly, the line width of metal lines provided in the plurality of wiring levels or metallization layers may also have to be adapted to the reduced feature sizes in the device layer in order to account for the increased packing density. Consequently, the actual feature dimensions may be well below the wavelength of currently used light sources provided in current lithography systems. For example, currently in critical lithography steps, an exposure wavelength of 193 nm may be used, which therefore may require complex techniques for finally obtaining resist features having dimensions well below the exposure wavelength. Thus, highly non-linear processes are typically used to obtain dimensions below the optical resolution. For example, extremely non-linear photoresist materials may be used, in which a desired photochemical reaction may be initiated on the basis of a well-defined threshold so that weakly exposed areas may not substantially change at all, while areas having exceeded the threshold may exhibit a significant variation of their chemical stability with respect to a subsequent development process. The usage of highly non-linear imaging processes may significantly extend the capability for enhancing the resolution for available lithography tools and resist materials.

Due to the complex interaction between the imaging system, the resist material and the corresponding pattern provided on the reticle, even in highly sophisticated imaging techniques, which may possibly include optical proximity corrections (OPC) and the like, the consistent printing of latent images, that is, of exposed resist portions which may be reliably removed or maintained, depending on the type of resist used, may also significantly depend on the specific characteristics of the respective features to be imaged. For instance, it has been observed that line-like features having a specific design width and a design length may require specific exposure recipes for otherwise predefined conditions, such as a specified lithography tool in combination with a specific reticle and resist material, in order to reliably obtain the desired critical width dimension, while the length dimension is less critical, except for respective end portions, so-called end caps of the respective lines, which may also typically require respective corrections. Consequently, for other features having critical dimensions in two lateral directions, such as substantially square-like features, the same exposure recipe as used for line-like features may not be appropriate and may therefore require elaborated process parameters, for instance with respect to exposure dose and OPC and the like. Furthermore, the respective process parameters in such a highly critical exposure process may have to be controlled to remain within extremely tight process tolerances compared to a respective exposure process based on line-like features, which may contribute to an increasing number of non-acceptable substrates, especially as highly scaled semiconductor devices are considered. Due to the nature of the lithography process, the corresponding process output may be monitored by respective inspection techniques in order to identify non-acceptable substrates, which may then be marked for reworking, that is, for removing the exposed resist layer and preparing the respective substrates for a further lithography cycle. However, lithography processes for complex integrated circuits may represent one of the most dominant cost factors of the entire process sequence, thereby requiring a highly efficient lithography strategy so as to maintain the number of substrates to be reworked as low as possible. Consequently, the situation during the formation of sophisticated integrated circuits may increasingly become critical with respect to throughput.

With reference to FIGS. 1a-1c, a typical process sequence for forming vias or contacts and line-like features may be described in order to more clearly demonstrate the problems involved in the manufacturing process for forming advanced semiconductor devices.

FIG. 1a schematically illustrates a top view of a semiconductor device 100 in a manufacturing stage after a respective lithography process including a respective development step. The semiconductor device 100 may comprise a resist layer 110, which may be formed above a respective material layer as will be described later on with reference to FIG. 1b. The resist layer 110 has formed therein respective resist openings 110A having lateral dimensions in a length direction L and a width direction W, indicated as 110L, 110W. The respective lateral dimensions 110L, 110W may be similar, if, for instance, a substantially square-like feature is to be formed on the basis of the resist openings 110A. As previously explained, for highly sophisticated applications, the corresponding lateral dimensions 110L, 110W may represent critical dimensions for the device layer under consideration, i.e., these lateral dimensions may represent the minimum dimensions to be printed in the corresponding device level. The respective resist openings 110A are to be used as etch masks for patterning the underlying material layer in order to form respective openings therein that, in turn, may be used for forming appropriate device features, such as contacts, vias and the like, which may provide contact to overlying and underlying device features, such as metal regions, metal lines and the like. For example, it may be assumed that a connection to a respective line feature is to be provided in a subsequent device level, wherein it may be assumed that the corresponding line features, indicated by dashed lines 120A, may have substantially the same critical dimension in the width direction W.

FIG. 1b schematically illustrates the semiconductor device 100 in a cross-sectional view taken along the line Ib-Ib from FIG. 1a. The semiconductor device 100 in this manufacturing stage comprises a substrate 101, which may represent an appropriate carrier material including the respective material layers (not shown) which may comprise device features, such as transistors, capacitors and the like. Furthermore, a dielectric layer 102 comprised of any appropriate dielectric material, such as silicon dioxide, silicon nitride, combinations thereof and the like, is formed above the substrate 101 and comprises a respective opening 102A having similar lateral dimensions as the respective resist opening 110A. Furthermore, a further dielectric layer 103, for instance an anti-reflective coating (ARC) layer and the like, may be formed on the dielectric layer 102 in order to assist the respective exposure process for patterning the resist layer 110. The layer 103 may be formed of any appropriate material, such as silicon oxynitride, silicon nitride and the like.

The semiconductor device 100 as shown in FIG. 1b may be formed on the basis of the following processes. After providing respective device features in and above the substrate 101, the dielectric layer 102 may be deposited on the basis of well-established manufacturing techniques, which may comprise chemical vapor deposition (CVD) processes and the like. For instance, sophisticated CVD techniques for forming silicon nitride, silicon dioxide and the like are well established in the art, for instance for providing a reliable encapsulation of respective device features, such as transistors and the like. After the deposition of the layer 102, a respective planarization process may be performed, if required, to enhance the surface topography prior to forming the layer 103 and the resist layer 110. In other cases, the respective surface topography may be maintained and may be taken into account by appropriately forming the resist layer 110.

The resist layer 110 may be prepared for a subsequent exposure process on the basis of established treatments, such as pre-exposure bake and the like, to enhance process uniformity. Thereafter, the resist layer 110 may be exposed on the basis of a respective photomask or reticle, which may comprise corresponding mask features that may possibly be designed on the basis of appropriate correction techniques in order to take into account the respective non-linearity of the corresponding exposure process, as previously described. In other cases, any other appropriate techniques, such as phase shift masks and the like, may be used. During the exposure process, typically a well-defined exposure field may be illuminated by an optical beam that is modulated by the pattern included in the reticle to transfer the reticle pattern into the resist layer 110 in order to define a respective latent image. That is, the latent image may be understood as a respective portion of the resist layer 110 receiving a significant amount of radiation energy in order to modify the photo-chemical behavior of the corresponding resist material. In the present case, it may be assumed that a positive resist may be used which may become soluble upon exposure during a subsequent development step. Consequently, during the respective exposure process, the substrate 101 is appropriately aligned and thereafter a certain exposure dose is transferred into the respective exposure field under consideration in order to create the respective latent images, wherein the respective mask features and/or the imaging techniques may be selected such that a certain threshold of energy for generating a required photochemical modification may be accomplished within specified areas according to the desired design dimensions of the respective features. That is, in the above-described case, the respective exposure process is designed in combination with respective mask features so as to deposit sufficient energy within an area corresponding to the openings 110A having the lateral dimensions 110L, 110W in order to obtain a substantially complete removal of the respective exposed resist material during the subsequent development step.

Due to the minimum dimensions in both lateral directions, respective process parameters of the exposure process, such as exposure dose and the like, as well as of any pre-exposure and post-exposure processes, may have to be maintained within tightly set process margins in order to obtain the respective resist openings 110A since even some incompletely opened areas within the resist opening 110A may result in corresponding irregularities during the subsequent etch process for forming the openings 102A in the dielectric layer 102. Hence, after developing the exposed resist layer 110, i.e., after removing exposed portions of the resist material, a respective inspection of the substrate 100 may be performed in order to identify exposure fields outside the respective specifications. Due to the very tight process margins for forming the critical openings 110A, a corresponding high number of non-acceptable exposure fields, each of which may be exposed on the basis of an individually adjusted exposure dose, may occur in particular if highly scaled devices are considered, in which the respective lateral dimensions 110L, 110W may be approximately 100 nm and less.

FIG. 1c schematically illustrates the device 100 in a cross-sectional view according to the section Ic-Ic in FIG. 1a in an advanced manufacturing stage. Here, the opening 102A may be filled with an appropriate material, such as a metal, and a further dielectric layer 104 may be formed above the layer 102 which comprises a further line-like feature 104A. Furthermore, a respective resist layer 120, possibly in combination with a respective ARC layer 113, may be formed above the dielectric layer 104, including respective trench-like openings 120A having the lateral dimension 110W. In this case, it is assumed that the width of the respective resist opening 120A may substantially correspond to the critical dimensions of the resist openings 110A.

A respective process flow for forming and patterning the layers 104, 113 and 120 may comprise substantially the same process steps as described with reference to FIG. 1b. However, as previously explained, during the corresponding lithography sequence including any pre- and post-exposure processes, it has been observed that corresponding process tolerances may be less critical compared to the exposure process for forming the openings 110A, which is believed to be caused by the lack of respective boundary conditions in the lateral length direction L. For example, the respective resist opening 120A may be formed with a reduced exposure dose compared to the opening 110A, while other process parameters may be less critical, thereby providing a moderately wider process window for the corresponding lithography process for forming the line-like features 120A.

Since respective resist openings 110A for contacts and vias may have to be provided at various manufacturing stages, the very tight process tolerances to be met may thus significantly contribute to a reduced overall throughput of the per se very cost intensive lithography module, which may therefore significantly contribute to overall production costs. Furthermore, the respective exposure processes may be restricted to highly advanced lithography tools only, thereby increasing even more the overall production costs.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the subject matter disclosed herein relates to process techniques in which a critical exposure process may be replaced by two less critical exposure processes in order to obtain a desired design dimension in two different lateral directions on the basis of less critical process margins, thereby significantly contributing to process flexibility, since less sophisticated lithography tools may be used, while the error rate of the entire exposure process may be reduced. To this end, a critical resist feature may be formed on the basis of two exposure steps, in which two less critical design features may be combined to obtain a respective latent image portion that defines the desired critical resist feature to be formed.

In one illustrative method disclosed herein, a first exposure process is performed to form a first latent image in a resist layer provided above a material layer of a semiconductor device. The method further comprises performing a second exposure process to form a second latent image in the resist layer, wherein the first and second latent images have a common portion wherein the second latent image has different dimensions in two orthogonal lateral directions. Furthermore, the method comprises developing the first and second latent images in a common development process to form a resist feature and using the resist feature to form a device feature in the material layer, wherein the device feature has lateral dimensions that substantially correspond to the common portion.

According to another illustrative method disclosed herein, a resist layer provided above a dielectric material is exposed by a first exposure process and a second exposure process. The first and second exposure processes produce a first elongated exposed portion and a second exposed portion, wherein the first and second exposed portions intersect each other to define a first common portion that is exposed twice. The method further comprises developing the resist layer to obtain a first resist opening in the resist layer, wherein the first resist opening has lateral dimensions that substantially correspond to lateral dimensions of the first, twice-exposed portion.

According to yet another illustrative embodiment disclosed herein, a method comprises performing a first exposure process with a first exposure dose to define a first elongated exposed portion in a resist layer that is provided above a material layer of a semiconductor device. The first exposure dose results in incomplete resist removal for a predefined developing recipe. The method further comprises performing a second exposure process with a second exposure dose to define a second elongated exposed portion in the resist layer, wherein the second exposure dose results in incomplete resist removal for the predefined developing recipe, wherein the second elongated portion intersects the first elongated portion so as to define a region of increased exposure dose.

### BRIEF DESCRIPTION OF THE DRAWINGS

The disclosure may be understood by reference to the following description taken in conjunction with the accompanying drawings, in which like reference numerals identify like elements, and in which:

FIG. 1a schematically illustrates a top view of a semiconductor device including resist openings having critical dimensions in two lateral directions formed in accordance with conventional exposure strategies;

FIGS. 1b-1c schematically illustrate cross-sectional views of the semiconductor device shown in FIG. 1a;

FIG. 2a schematically illustrates a top view of a resist layer including latent images formed by a double exposure process according to illustrative embodiments;

FIGS. 2b-2d schematically illustrate cross-sectional views of the device of FIG. 2a during various manufacturing stages according to illustrative embodiments;

FIG. 3a schematically illustrates a cross-sectional view of a semiconductor device at a manufacturing stage for patterning a dielectric material to obtain critical openings therein according to illustrative embodiments;

FIG. 3b schematically illustrates a top view of the device of FIG. 3a;

FIG. 3c schematically illustrates a top view of the device of FIG. 3b with respective latent images formed in accordance with a double exposure process according to illustrative embodiments; and

FIG. 3d schematically illustrates the semiconductor device in a further advance manufacturing stage.

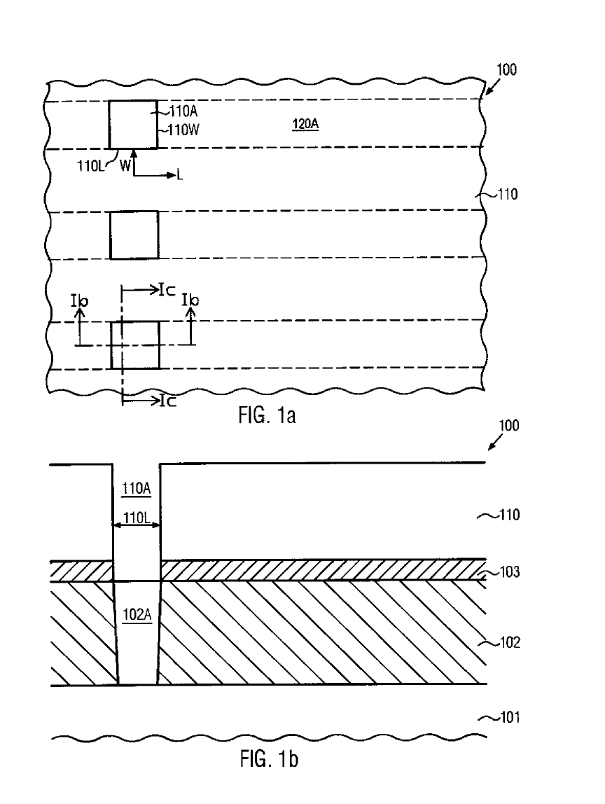

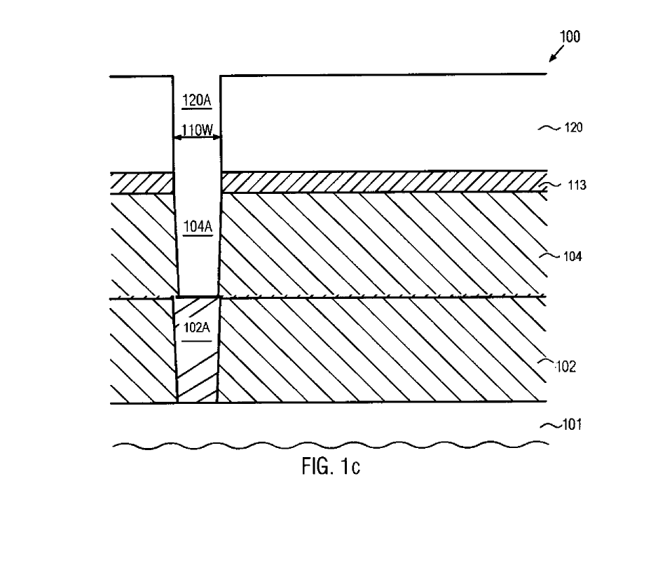

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the subject matter disclosed herein relates to process techniques for enhancing the patterning of critical device features, which, in some illustrative embodiments, represent respective openings in a dielectric material, which may subsequently be filled with an appropriate conductive material. Typically, respective device features, such as contacts, vias and the like, may have similar dimensions in respective lateral directions, thereby requiring tight process parameter control and sophisticated exposure tools during the corresponding process for forming the respective resist mask, as previously explained. In order to significantly relax the respective requirements, i.e., providing less strict process windows for the overall process sequence, it is taken advantage of the fact that critical dimensions in one specific lateral dimension may be obtained on the basis of less critical process requirements, as long as the corresponding orthogonal lateral dimension is significantly larger. Consequently, by appropriately combining respective less critical design features, a respective intersection or common portion may be defined, which may have the desired design dimensions in both lateral directions without requiring a highly complex and critical exposure process sequence. That is, at the respective common portion or intersection of the respective less critical design features an area may be defined in which the accumulated exposure dose is sufficiently high so as to result in a substantially complete resist removal, if positive resists are considered, or a substantially complete removal of the surrounding resist material, if negative resists are considered, while respective surrounding resist material portions may not receive the required amount of exposure energy. In this way, the completely exposed common portion may have substantially the desired design dimension, thereby providing a sufficient masking effect during a subsequent patterning process in order to appropriately pattern a respective underlying material layer. Hence, each of the two exposure steps may be performed with a reduced exposure dose, thereby even further reducing the effect of the exposure on resist material portions located outside the common portion, while nevertheless the required high exposure dose may be obtained in the common portion. In this way, the overall process time for each exposure step may be significantly reduced, thereby maintaining the overall process time for both exposure steps at a moderately low level, wherein the reduced amount of substrates to be reworked in combination with the enhanced process flexibility, for instance in terms of the possibility of using less advanced lithography tools, may even compensate or over-compensate for process time required for the additional second exposure step.

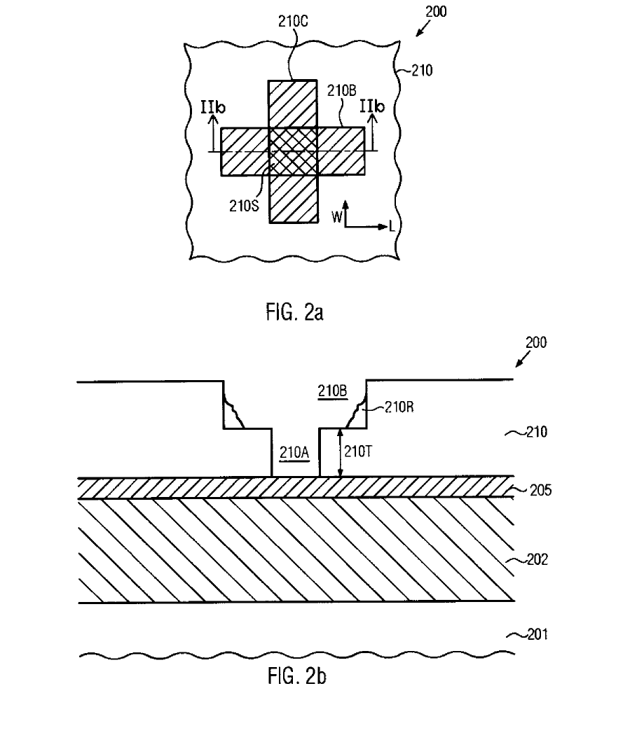

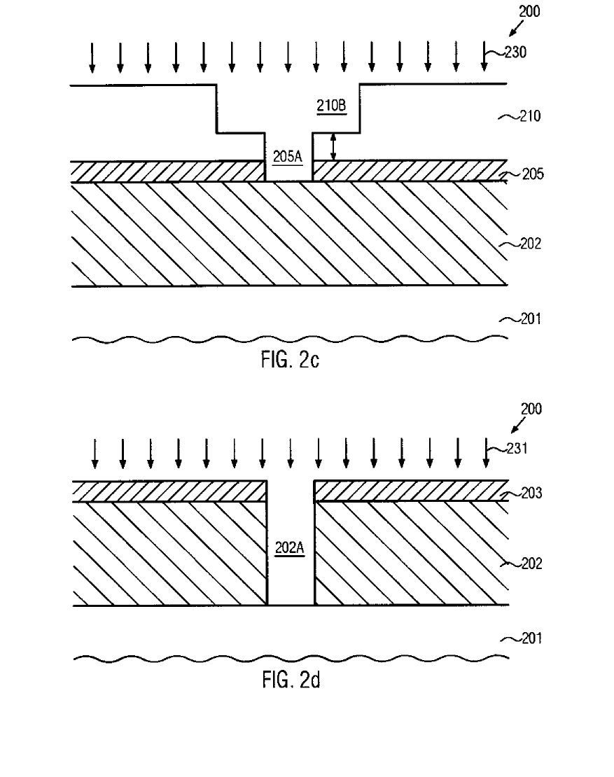

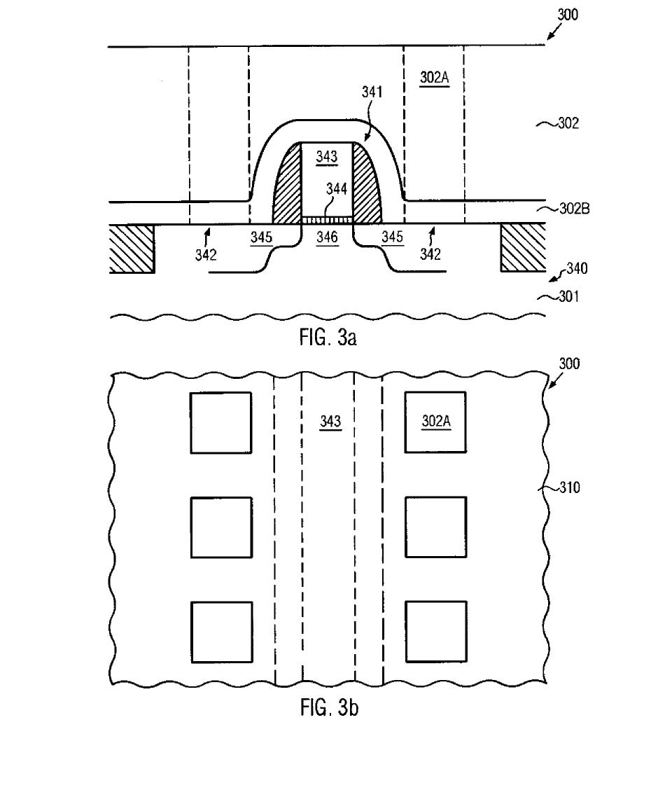

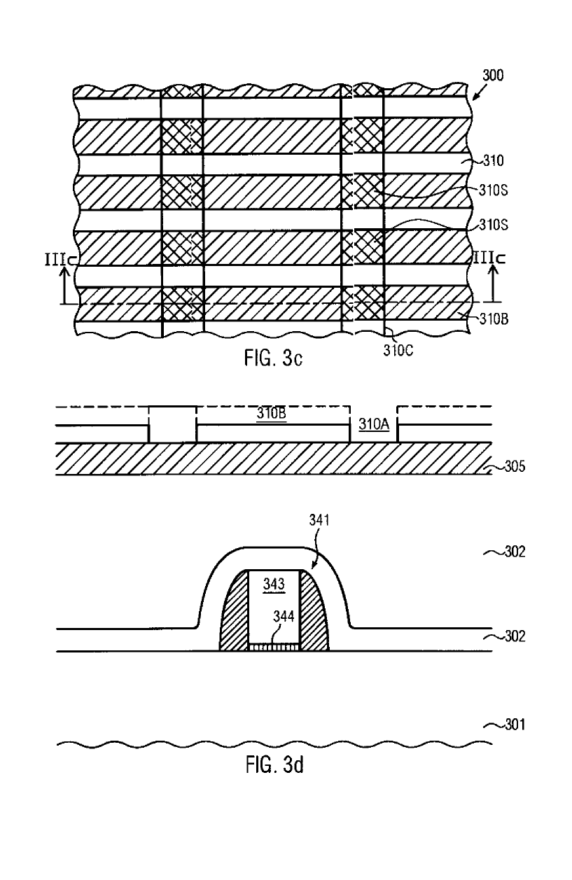

FIG. 2a schematically illustrates a top view of a semiconductor device 200 at a manufacturing stage in which critical features have to be patterned on the basis of a resist layer 210. For instance, in some illustrative embodiments, the respective device features, which may have to be formed on the basis of respective resist features of the layer 210, may represent contact portions connecting to transistor areas or any other devices in a device level of the semiconductor device 200, as will be described in more detail with reference to FIGS. 3a-3d. In other illustrative embodiments, the respective device features may represent vias, i.e., metal-containing regions connecting to different metallization levels of a respective metallization structure of the semiconductor device 200. Thus, the respective device features may have similar lateral dimensions in two different lateral directions, as previously explained. For obtaining the desired design dimensions of the respective device features, a first latent image 210B may be formed in the resist layer 210, wherein the first latent image 210B may be understood as a resist material portion, which may have received a predefined exposure dose during a first exposure process. Similarly, a second latent image 210C may be formed in the resist layer 210, wherein the latent image 210C may be defined as an exposed resist material having received a predefined exposure dose during a second exposure step. As is shown, the first and second latent images 210B, 210C may have been formed such that an intersection or common portion 210S is defined which has received the accumulated exposure dose provided by the first and second exposure steps. In some illustrative embodiments, at least one of the first and second latent images 210B, 210C has different dimensions in the respective length direction or width direction indicated as L, W wherein the smaller one of the respective lateral dimensions may represent a critical dimension for the corresponding device layer of interest. Consequently, the respective critical dimension may be obtained on the basis of less critical process constraints compared to the respective process sequence that may have to be used in conventional strategies, in which a latent image corresponding to the intersection 210S is formed in a single exposure step, as previously explained. Consequently, the other one of the first and second latent images 210B, 210C may be formed on the basis of any appropriate dimensions so as to finally define the desired size and shape of the intersection or common portion 210S.

In some illustrative embodiments, the lateral dimensions 210L, 210W of the intersection 210S may be of comparable size and may therefore represent critical dimensions in the respective device layer. In this case, the width of the first latent image 210B and the length of the second latent image 210C may be substantially identical in order to define a substantially square shaped intersection 210S. Thus, in this embodiment, the respective first and second latent images 210B, 210C represent bar-like features or represent elongated features, i.e., features that have dimensions in two orthogonal lateral directions that are different. As previously explained, respective resist features of elongated shape may be formed on the basis of less critical process requirements, in particular when the exposure conditions at the respective end portions of each of the elongated features may not be relevant for defining the intersection 210S. Consequently, any distortions at the respective longitudinal end portions of the first and second latent images 210B, 210C which may usually require highly complex corrections, such as OPC corrections, may be neglected since the respective distortions may not negatively affect the interesting intersection 210S.

Hence, the resist layer 210, which may have substantially the same or a similar configuration as is also used for the semiconductor device 100, as previously explained, may be efficiently patterned on the basis of the following processes. After forming any underlying material layers, as will be explained later on with reference to FIG. 2b, the resist layer 210 may be formed and prepared for a subsequent double exposure process wherein, in a first exposure step, respective process parameters may be selected so as to obtain the first latent image 210B. That is, an appropriate mask may be provided having formed therein a corresponding mask feature for obtaining the latent image 210B, wherein, however, only a central portion thereof may be relevant, thereby reducing any efforts in terms of additional corrections with respect to per se critical end portions. For instance, well-established mask features of a line-like nature as are typically used in other device layers may be used for this purpose. Contrary to a conventional exposure procedure for imaging a line-like latent image into the resist layer, the exposure dose may be significantly reduced, for instance to approximately 50-80% of an exposure dose that would actually be used for an exposure process, when the latent image 210B would have to actually be used as a resist mask. That is, if a positive resist is considered, the respective exposure dose is selected such that developing of the first latent image 210B solely on the basis of this exposure dose does not result in a complete removal of the corresponding exposed resist material. Appropriate process parameters for the first exposure step may be obtained on the basis of conventional single step recipes for line-like features wherein, however, the respective exposure dose may be scaled so as to obtain the above-specified range. Hence, respective local variations in exposure dose that may occur in individual exposure fields and across the entire substrate of the device 200 may also be automatically taken into consideration by respectively scaling the exposure dose. Consequently, the exposure step may be performed on the basis of less critical process parameters with a reduced exposure dose, thereby contributing to a reduced overall process time compared to a single step exposure for obtaining a feature corresponding to the intersection 210S. It should be appreciated that, as previously explained, the intersection 210S, when formed in a single step exposure, would require even higher exposure doses and thus increased process time.

After the first exposure step, a second exposure step may be performed, for instance on the basis of substantially the same process parameters as the first exposure step, wherein the combined exposure dose in the intersection 210S may now provide substantially complete exposure of the resist material required in the subsequent development step so as to form a corresponding resist feature having the dimensions of the intersection 210S. Thus, the two exposure steps may be performed with less critical process margins, thereby forming the intersection 210S having the desired dimensions in both lateral directions L, W with only a moderately higher overall process time during the corresponding double exposure process sequence. Due to the less critical process windows in the first and second exposure steps, a significantly increased flexibility in performing the respective exposure sequence may be obtained, since less sophisticated exposure tools may possibly be used and also the respective process thread comprising the various steps, such as pre-exposure and post-exposure processes, may be less critical. That is, in a complex manufacturing environment, a plurality of lithography tools, reticles, post- and pre-exposure tools are typically provided which may be supplied with respective substrates according to sophisticated schedules. Due to the increased process window, the processing of the respective substrates may be scheduled on the basis of tool availability and other throughput-related parameters rather than on the basis of process-related issues, thereby possibly contributing to an overall increase in throughput, since availability of highly sophisticated lithography tools may be increased for other more critical lithography processes. Furthermore, the failure rate for defining the intersection 210S may be significantly lower compared to a single step exposure process as previously described, thereby significantly reducing the number of substrates requiring rework.

FIG. 2b schematically illustrates the semiconductor device 200 in a cross-sectional view as indicated in FIG. 2a. In this manufacturing stage, the device 200 may comprise a substrate 201 including any appropriate carrier material, such as silicon-based semiconductor material, a silicon-on-insulator (SOI) substrate, etc., in which may be formed respective circuit elements, such as transistors, capacitors and the like, as are typically required for the device 200. In other cases, the substrate 201 may represent an appropriate base material which may or may not include respective circuit elements, wherein a layer of vertical connections or openings may have to be formed on the basis of critical lateral dimensions. The semiconductor device 200 may comprise a material layer 202 that is to be patterned on the basis of the intersection 210S. The material layer 202 may represent any appropriate material, such as a dielectric material in accordance with device requirements. For instance, the material layer 202 may be comprised of one or more layers, such as dielectric materials provided between respective metallization levels of sophisticated integrated circuits. For example, low-k dielectric materials, i.e., materials having a relative permittivity of 3.0 and less, may be frequently used in sophisticated metallization structures, possibly in combination with other dielectric materials, wherein respective vertical electrical connections, also referred to as vias, may provide the interlevel connection between two metal line layers.

Furthermore, a mask layer 205 may be formed above the material layer 202, wherein the mask layer 205 may be comprised of any appropriate material having a required high etch resistance with respect to a corresponding etch recipe used to pattern the material layer 202 in a subsequent manufacturing stage. For example, the mask layer 205 may be comprised of silicon nitride, silicon oxynitride, polymer material and the like, as long as it is appropriate for acting as an etch mask. Consequently, the mask layer 205 may be provided with a significantly lower thickness compared to the material layer 202. Moreover, the resist layer 201 may be formed above the mask layer 205 and has formed therein an opening 210A having lateral dimensions substantially corresponding to the intersection 210S of FIG. 2a. The opening 210A may extend substantially down to the mask layer 205 due to the high exposure dose received during the first and second exposure steps, as previously described. Furthermore, a respective elongated opening of significantly reduced depth, which may also be denoted as opening 210B, may be formed that substantially corresponds to the latent image 210B of FIG. 2a. It should be appreciated that the configuration of the opening 210B may be less precisely defined due to the significantly reduced exposure dose and due to possible distortions at end caps thereof, which may possibly result in respective material residues 210R, which, however, may not negatively affect the configuration of the opening 210A.

The device 200 as shown in FIG. 2b may be formed on the basis of the following processes. After providing the substrate 201 and forming any device features therein, the material layer 202 may be formed on the basis of any appropriate process technique, such as chemical vapor deposition (CVD) or other deposition processes, spin-coating and the like, as demanded by device requirements. Thereafter, the mask layer 205 may be formed with an appropriate thickness and material composition so as to act as an etch mask for patterning the material layer 202 in a subsequent etch process. In some illustrative embodiments, the layer 205 may additionally provide respective optical characteristics so as to act as an anti-reflective coating (ARC) layer during the respective first and second exposure processes for defining the first and second latent images 210B, 210C. For instance, the layer 205 may be formed of silicon oxynitride with an appropriate material composition so that the corresponding thickness may provide the desired reduction of back reflection into the resist layer 210 and also provide a sufficient thickness during a subsequent etch process. In other cases, other materials, such as polymer materials and the like, may be provided with a desired thickness to provide the optical characteristics and the corresponding etch resistance. Thereafter, the resist layer 210 may be formed and prepared according to well-known techniques, as are also described with reference to the resist layer 110. Thereafter, the first and second latent images 210B, 210C may be produced on the basis of a respective double exposure sequence as described above with reference to FIG. 2a. Thereafter, the latent images 210B, 210C may be developed in a common developing process, wherein respective process parameters for the development of line-like features may be used. During the corresponding development process, the respective photochemical modification of the intersection 210S may extend substantially down to the mask layer 205, thereby allowing the removal of the intersection 210S so as to form the opening 210A, while other exposed portions of the first and second latent images 210B, 210C, having seen a significantly reduced exposure dose, may result in a significantly less efficient material removal, possibly forming the respective residues 210R. Consequently, the single exposed portions of the first and second latent images 210B, 210C may provide a sufficient residual layer thickness 210T so as to reliably act as an etch mask for patterning the mask layer 205 to transfer the opening 210A into the mask layer 205.

FIG. 2c schematically illustrates the semiconductor device during a final phase of a corresponding etch process 230 for etching the mask layer 205, for instance on the basis of well-established anisotropic etch recipes, wherein the resist layer 210, and in particular the respective openings 210B and 210C (not shown), may provide sufficient etch resistance so as to reliably form a corresponding opening in the mask layer 205, indicated as 205A, having substantially the same dimensions as the resist opening 210A. Thus, the opening 205A may then be used as a corresponding etch mask for patterning the material layer 202. For this purpose, the etch process 230 may be continued if the respective etch ambient has the required characteristic for etching through the material 202 while nevertheless exhibiting a desired degree of selectivity with respect to the material of the layer 205. In this case, the resist layer 210 may remain until the process 230 is completed and any resist residuals may be removed in a subsequent cleaning or etch step. In other illustrative embodiments, the resist layer 210 may be removed and an appropriate etch ambient may be established so as to pattern the material layer 202.

FIG. 2d schematically illustrates the device 200 during a corresponding etch process 231 performed on the basis of the mask layer 205 so as to obtain a respective opening 202A with lateral dimensions that substantially correspond to the lateral dimension of the initial resist opening 210A. The respective anisotropic etch process 231 may be performed on the basis of well-established process parameters, as previously explained.

With reference to FIGS. 3a-3d, further illustrative embodiments will now be described, in which respective contact openings are formed to connect to respective circuit elements provided in a device level of a semiconductor device.

FIG. 3a schematically illustrates a cross-sectional view of a semiconductor device 300 comprising a substrate 301 having formed thereabove a device level 340, which may be comprised of appropriately configured semiconductor portions in and above which may be formed one or more circuit elements 341, wherein, for instance, a transistor element may be shown to represent a respective circuit element. When representing a transistor element, the circuit element 341 may comprise a gate electrode 343 formed on a gate insulation layer 344, separating the gate electrode 343 from a channel region 346. Furthermore, respective drain and source regions 345 may be defined adjacent to the channel region 346. It should be appreciated that, in sophisticated semiconductor devices, a critical dimension of the transistor 341, i.e., a length of the gate electrode 343, that is, in FIG. 3a the horizontal dimension of the gate electrode 343, may be approximately 50 nm and even less. Furthermore, the circuit element 341 may be masked by a dielectric layer 302, which may be comprised of two or more individual layers, depending on the device requirements, for instance a layer 302B may be provided to act as an etch stop layer for patterning the remaining material of the layer 302. The layer 302 is to be patterned to provide respective contact openings 302A, shown in dashed lines, which have to extend to respective contact areas 342 in order to provide electrical contact to the circuit element 341.

The semiconductor 300 as shown in FIG. 3a may be formed on the basis of well-established process techniques in accordance with device requirements, as are also referred to above, and hence respective processes will not be described herein in more detail.

FIG. 3b schematically illustrates a top view of the device 300, wherein respective dimensions and locations of the respective contact openings 302A still to be formed are shown. For convenience, the respective gate electrode 343 is illustrated, although actually masked by the layer 302.

FIG. 3c schematically illustrates a top view of the device 300, wherein the device 300 comprises a resist layer 310 that may be used for patterning the respective openings 302A in a subsequent etch process. The resist layer 310 may comprise one or more first latent images 310B defined by a first exposure process on the basis of a first exposure dose that is selected so as to not result in a complete removal during a specified development process, as is previously explained. Similarly, one or more second latent images 310C may be defined during a second exposure step on the basis of a second exposure dose, which may be the same or different from the first exposure dose, which, however, is also selected so as to not result in a complete removal during the subsequent development process. Furthermore, the first and second latent images 310B, 310C are oriented such that a plurality of intersections or common portions 310S are formed which have received a double exposure dose, thereby resulting in substantially complete removal during the subsequent development process, as previously explained. The first and second latent images 310B, 310C may each be defined during a respective exposure step based on less critical process parameters as would be required when the respective areas corresponding to the intersection 310S would have to be defined in a single exposure step, as previously explained with reference to the latent images 210B, 210C. Consequently, the required lateral dimensions of the contact openings 302A may be obtained on the basis of a double exposure sequence with less critical process parameters, thereby providing the advantages described above.

FIG. 3d schematically illustrates a cross-sectional view of the device 300 corresponding to the section IIIc of FIG. 3c. Moreover, a respective development process may have been performed to substantially completely remove the material within the intersection 310S, thereby defining the respective openings 310A while also forming respective openings corresponding to the latent images 310B, 310C, however with a significantly reduced depth due to the reduced exposure doses used in the first and second exposure steps. For example, as seen in FIG. 3d, a respective opening 310B may be formed between adjacent openings 310A. Furthermore, a respective mask layer 305 may be provided between the material layer 302 to be patterned and the resist layer 310, as is also described with reference to the mask layer 205.

Thus, after patterning the resist layer 310 according to an appropriate development process, thereby defining the opening 310A, a subsequent etch process may be performed to transfer the opening 310A into the mask layer 305, which may then act as an etch mask for finally obtaining the respective openings 302A extending down to the contact areas 342, which may then be filled with an appropriate conductive material.

As a result, the subject matter disclosed herein provides an enhanced technique for forming respective resist features having similar lateral dimensions in two orthogonal lateral directions on the basis of a double exposure sequence, wherein, in one of the lateral directions, a significantly increased design dimension is used. By appropriately intersecting the respective latent images produced by the two exposure steps, a twice-exposed intersection or common portion may be formed having significantly smaller dimensions, which are therefore defined by less critical process parameters compared to a corresponding single step exposure process. In illustrative embodiments, line-like elements having a critical dimension in the width direction may be used on the basis of less critical process parameters and a significantly reduced exposure dose compared to a single exposure step for forming a contact or via opening, thereby providing enhanced process flexibility and reduced failure rate of the corresponding exposure process, in particular for highly sophisticated semiconductor devices requiring contacts and vias having lateral dimensions of 100 nm and even less. Furthermore, the concept of double exposure on the basis of less critical elongated features may be also advantageously applied to less critical device levels, thereby providing the potential for using less sophisticated lithography tools and thus obtaining significantly reduced overall production costs.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
performing a first exposure process to form a first latent image in a resist layer provided above a material layer of a semiconductor device;
performing a second exposure process to form a second latent image in said resist layer, said first and second latent images having a common portion, said second latent image having different dimensions in two orthogonal lateral directions;
developing said first and second latent images in a common development process to form a resist feature; and
using said resist feature to form a device feature in said material layer, said device feature having lateral dimensions substantially corresponding to said common portion.

2. The method of claim 1, wherein said first latent image has different dimensions in said two orthogonal lateral directions.

3. The method of claim 2, wherein said common portion has substantially equal dimensions in said two orthogonal lateral directions.

4. The method of claim 1, further comprising selecting a dose of said first exposure process and a dose of said second exposure process so as to avoid complete removal of exposed resist material outside said common portion.

5. The method of claim 1, further comprising forming a hard mask layer between said material layer and said resist layer and forming a mask feature in said hard mask layer on the basis of said resist feature.

6. The method of claim 1, wherein said first and second latent images have an elongated configuration in a plane defined by said two orthogonal lateral directions and wherein length directions of said elongated configurations are not collinear.

7. The method of claim 1, wherein forming said device feature comprises etching an opening into said material layer, said opening having lateral dimensions substantially corresponding to said common portion.

8. The method of claim 7, wherein said opening connects to a transistor region.

9. The method of claim 7, wherein said opening is a via connected to a metal line of a metallization layer of said semiconductor device.

10. A method, comprising:
exposing a resist layer provided above a dielectric material by a first exposure process and a second exposure process, said first and second exposure processes producing a first elongated exposed portion and a second exposed portion, said first and second exposed portions intersecting each other to define a first common portion that is exposed twice; and
developing said resist layer to obtain a first resist opening in said resist layer, said first resist opening having lateral dimensions that substantially correspond to lateral dimensions of said first common twice-exposed portion.

11. The method of claim 10, further comprising using said first opening to form a mask opening in a mask material layer provided between said resist layer and said material layer.

12. The method of claim 11, wherein exposing said resist layer comprises producing a third exposed portion intersecting said first exposed portion to define a second common portion that is exposed twice and forming a second resist opening.

13. The method of claim 12, further comprising forming a first contact and a second contact on the basis of said first and second resist openings, said first and second contacts connecting to a contact area of a transistor element.

14. The method of claim 10, wherein said first and second exposure processes are performed with a dose that is less than required for completely removing said first and second exposed portions during developing said resist layer.

15. The method of claim 10, wherein said first and second exposed portions have substantially the same lateral dimensions.

16. The method of claim 10, wherein a width of at least one said first and second elongated exposed portions represents a critical dimension of at least one of said first and second exposure processes.

17. A method, comprising:
performing a first exposure process with a first exposure dose to define a first elongated exposed portion in a resist layer provided above a material layer of a semiconductor device, said first exposure dose resulting in incomplete resist removal for a predefined developing recipe; and
performing a second exposure process with a second exposure dose to define a second elongated exposed portion in said resist layer, said second exposure dose resulting in incomplete resist removal for said predefined developing recipe, said second elongated portion intersecting said first elongated portion to define a region of increased exposure dose, said increased exposure dose resulting in substantially complete removal of resist material for said predefined developing recipe.

18. The method of claim 17, further comprising developing said resist layer to form a resist opening in said resist layer, wherein lateral dimensions of said resist opening substantially correspond to lateral dimensions of said region.

19. The method of claim 18, further comprising forming an etch mask on the basis of said developed resist layer and using said etch mask to pattern said material layer to form an opening therein, said opening substantially corresponding to said resist opening.

20. The method of claim 19, wherein said opening represents a contact opening connecting to a contact area of a transistor element.

21. The method of claim 19, wherein said opening represents a via opening connecting to a trench used for forming a metal line in a metallization layer of said semiconductor device.
